(19) United States
(12) Patent Application Publication
(10) Pub. No.: US 2002/0160606 A1
(43) Pub. Date: Oct. 31, 2002

(54) Method for material removal from an in-process microelectronic substrate

(76) Inventors: Kevin L. Siefering, Excelsior, MN (US); Paul Deaton, San Jose, CA (US)

Correspondence Address: APPLIED MATERIALS, INC., 2881 SCOTT BLVD. M/S 2061, SANTA CLARA, CA, 95050, US

(21) Appl. No.: 10/076,115

(22) Filed: Feb. 14, 2002

Related U.S. Application Data
(60) Provisional application No. 60/268,766, filed on Feb. 14, 2001.
(60) Provisional application No. 60/268,660, filed on Feb. 14, 2001.

(51) Int. Cl. H01L 21/302; H01L 21/461

(52) U.S. Cl. 438/689

(57) ABSTRACT

A method for removing a material from a surface of an in-process, microelectronic substrate is provided. The method comprises providing a material-removing composition in the form of a liquid and flash vaporizing the liquid, thereby forming a material-removing vapor. The resulting vapor is then contacted with the material on the substrate. Preferred substrates include those used to make microelectronic articles such as semiconductor wafers and those used to make electric circuits, displays such as computer displays, optical storage media such as CD-ROM or DVD discs and other materials and products.

### BACKGROUND OF THE INVENTION

1. Field of the Invention

The invention relates to a method and apparatus for removal of material from an in process microelectronic substrate. More particularly, the present invention relates to a method and apparatus for removal of material from an in process microelectronic substrate utilizing a material-removing vapor.

2. Description of the Related Art

Certain substrates are etched and/or stripped, cleaned, rinsed and dried as part of processes for preparing a desired end product. Such substrates include those used in the manufacture of microelectronic devices (e.g., semiconductor wafers, integrated circuits), display screens (e.g., those comprising liquid crystals), circuit boards (e.g., those made of a synthetic material) and other commercially significant substrates. Many methods are known for etching, stripping, etc. using a variety of commercial processing equipment. Depending on product requirements, substrate surfaces are processed with one or more processing fluids.

With respect to the processing of substrates used to make microelectronic devices, the steps of cleaning, etching and/or stripping, rinsing and drying are preferably carried out in a virtually contaminant-free environment. Various types of available processing equipment are capable of exposing one or a number of wafer surfaces to different processing fluids (e.g., liquids and/or gases), to accomplish one and preferably a series of surface processing operations. These machines can perform a series of various cleaning, etching and stripping steps, sometimes followed by rinsing and drying steps, to a virtually contaminant-free surface. These steps involve the application of a suitable processing chemical(s) to the substrate surface, e.g., a gaseous or liquid cleaning solution or an etching agent. Process fluids used in these processes can be applied to the substrates as liquids, gases, or combinations thereof.

U.S. Pat. No. 5, 571,375 describes removing a native oxide film on a silicon wafer surface positioned within a reaction chamber by supplying mixed vapor of hydrogen fluoride and substantially high concentration alcohol to the chamber. (The alcohol, such as isopropyl alcohol (“IPA”), is one group of chemicals that enables, enhances, or, if you will, catalyzes the etching effect carried out by the hydrogen fluoride.) It is noted that the preparation of the hydrogen fluoride/alcohol vapor mixture involves the step of generating an azeotropic concentration mixture of hydrogen fluoride and alcohol and the step of generating vapor of high concentration alcohol solution. Use of an azeotropic solution of hydrogen fluoride and alcohol is a known approach for providing a substantially consistent vapor concentration of the hydrogen fluoride and alcohol in the reaction chamber.

Pending U.S. patent application Ser. No. 09/580,757 filed May 30, 2000, describes an apparatus and method for applying liquid-phase isopropyl alcohol onto a substrate positioned in a chamber and a subsequent process for flowing vapor-phase isopropyl alcohol into the chamber during a portion of the drying step. The vapor-phase isopropyl alcohol is generated by bubbling nitrogen gas through an amount of liquid-phase isopropyl alcohol.

### SUMMARY OF THE INVENTION

The present invention provides effective, economical and safe delivery of a material-removing vapor for removing material from a surface of an in-process, microelectronic substrate. With this invention, it is now possible to deliver highly corrosive or flammable constituents as a vapor and particularly mixtures of constituents in any desired content ratio in a vapor. The method comprises providing a material-removing composition in liquid form and flash vaporizing the liquid, thereby forming a material-removing vapor. The resulting vapor is then contacted with the material on the substrate.

### BRIEF DESCRIPTION OF THE DRAWINGS

FIG. 1 illustrates a schematic side view of an embodiment of the present invention.

FIG. 2 illustrates a schematic side view of another embodiment of the present invention.

### DETAILED DESCRIPTION OF PREFERRED EMBODIMENTS

The present invention provides a method for removing materials from the surface of an in-process microelectronic substrate wherein vapor for carrying out this removal process is safely and effectively generated and delivered in compositions and quantities required for carrying out the process. Thus, any desired quantity of a material-removing vapor may be generated on-demand for delivery to a microelectronic substrate having a material on the surface thereof for removal. Because flash vaporization quickly vaporizes the liquid made available to the process, any quantity from very small amounts to very large amounts of liquid may be vaporized in the ratio desired for most effective removal of the specific material to be removed.

The present invention also provides significant benefits in the type of the material-removing compositions that may be delivered to a substrate. Because of the nature of the process, flash vaporization generates a vapor having the same ratio of constituents as the liquid composition from which it is flash vaporized. This occurs regardless of the respective boiling points or liquid interactions of the constituents of the liquid. Until the present invention, the only way to assure a constant concentration ratio of any multiconstituent vapor system was to utilize an azeotropic mixture, so that the ratio of the resulting vapor constituents was fixed at the azeotropic ratio. Prior art systems that desired to utilize a constant concentration ratio vapor system therefore were limited to the azeotropic ratio of constituents that formed an azeotrope. With the present invention, it is now possible to provide a constant ratio in the vapor phase for any combination of constituents, regardless of whether an azeotropic solution is utilized. Indeed, the present invention provides significantly more flexibility in providing a vapor from a mixture of liquid constituents that form an azeotrope, because it is now possible to provide a vapor having any desired constituent ratio without restriction to the azeotropic ratio. Further, it is now possible to provide a constant concentration vapor even from constituents that do not form an azeotrope, but which would otherwise separate at different ratios because of their different volatilization equilibria. This provides benefits in two compositional aspects, first, in the freedom to select any ratio of components in a composition to be contacted with a substrate as a vapor and, second, in the ability to use unique compositions, such as emulsions, suspensions, mixtures of immiscible liquids and the like, that were difficult or impossible to provide in consistent vapor form prior to the present invention.

A prior art technique for providing a vapor having multiple constituents with different vapor pressures would be to generate separate vapors from pure liquid solutions and to combine these vapors later only in the vapor phase to provide the desired ratio of constituents for contacting the intended substrate. However, this approach requires storage of the constituent liquids in their pure state, which may be inconvenient or expensive. Because the heating of large quantities of liquid is not required in the present invention, expense may be spared and safety may be enhanced by using the process of the present invention.

Additionally, the present invention provides better control of the content of the vapor to be delivered to the substrate. A substantial benefit is realized in the present process because it is now possible to predilute the pure constituents with the assurance that the generated vapor will have the same composition as the starting liquid. Better and more precise control of the content of the vapor is possible because it is easier to control the amount of liquid constituents to be added to a solution than it is to precisely control the amount of separate vapor constituents to be combined to a single vapor composition. Small variations in the concentration of vapor from one portion of the vapor to another result in a very substantial error in the concentrations of constituents in a vapor that is contacted with the substrate. In contrast, small variations in the concentration of constituents in a pre-mixed liquid solution result in less significant error in the concentrations of constituents in a vapor that is contacted with the substrate.

Another particular advantage of the present invention is that it is now possible to use commercially available liquid solutions in the production of material-removing vapors. As discussed above, in prior art systems if it was desired to have a constant concentration vapor contacted with a material to be removed, it was necessary to utilize a liquid that formed an azeotrope. The most efficient way to provide the constant concentration vapor was to provide the source liquid in its azeotropic ratio, so that the process would not have to be stopped when one of the components was exhausted from the liquid source. Unfortunately, such liquid source compositions are not always commercially readily available in their azeotropic ratio. Instead, there are other standard concentrations of material-removing liquids available, such as for example 49% HF in water, which is highly useful as a material-removing liquid, but which is not been heretofore been easily usable for providing a vapor. The present invention enables the use of such a readily available solution in a highly efficient manner.

The present invention further provides processing efficiencies and economic benefit by streamlining the process for generating vapor to be contacted with a substrate. In the conventional process for generating etching vapor, the vapor is obtained by evaporation from a reservoir of liquid, sometimes assisted by heating the reservoir of liquid or bubbling an inert gas such as nitrogen therethrough. The prior art vapor generation processes required storage of large liquid reservoirs of the desired chemical, with heating of the bulk solution, even though not all of the heated liquid would actually be delivered to the substrate in the treating process. In contrast, flash vaporization eliminates the need to generate vapor by heating large canisters of liquid or otherwise imparting large amounts of energy to bulk solutions. In flash vaporization, all of the desired material-removing liquid is converted to vapor. Additionally, because large quantities of liquid are not heated, enhanced safety may result by use of the method of the present invention.

The apparatus and methods of the present invention provide an ability to process various substrates to remove a material or materials on the surface of a substrate, such as undesirable materials, no longer desirable material, or materials that were intended to be removed (i.e., sacrificial materials). Preferred substrates include those used to make microelectronic articles such as semiconductor wafers, for example, comprising or containing silicon, gallium arsenide, or similar semiconducting materials, optionally having other materials coated thereon. Other preferred substrates include those used to make electric circuits, displays such as computer displays, optical storage media such as CD-ROM or DVD discs and other materials and products.

For purposes of the present invention, a liquid or vapor is considered to be “material removing” if it participates in any way in the removal of material from a substrate. Thus, the liquid or vapor may be itself capable of etching material, such as an acid, or may be a liquid or vapor that assists in the etching process, such as by hydrolyzing the acid or by acting as a catalyst. Additionally, the liquid or vapor is considered to be material removing if it rinses or dries a substrate surface.

More specifically, “etching” refers to removing at least a portion of a material from a substrate or a layer of a substrate. “Stripping” refers to removing all or substantially all of a material from a substrate or a layer of a substrate. “Rinsing” refers to removing by solvation of a material on the substrate. Such materials to be removed may, for example, include a prior processing ingredient, such as an etching or stripping ingredient. “Drying” refers to application of a surface tension reducing composition to assist in removal of liquid from the surface of a microelectronic substrate. The surface tension reducing composition modifies the flow or affinity characteristics of liquids resident on the surface of the substrate, to allow the liquid to flow or sheet more readily from the surface.

The term “flash vaporize” is used herein to mean vaporization by imparting a rapid change in the pressure or temperature environment of a liquid in a manner to rapidly convert substantially all of the available liquid to a vapor. Thus, flash vaporization is contrasted with equilibrium evaporation or vaporization, which is the progressive passage of a composition from liquid phase to the vapor phase at the vapor/liquid interface due to the concentration of the vapor adjacent the vapor/liquid interface. Equilibrium vaporization occurs until the vapor concentration rises to the point at which the vapor becomes saturated. In flash vaporization, the vapor phase is not saturated and there is no heat transfer limitation in conversion of liquid to vapor. Thus, the conversion to vapor is extremely rapid.

In liquid compositions that are solutions of more than one liquid constituent, flash vaporization provides vapor having the fraction of each constituent of the vapor composition the same as the fraction in the liquid composition from which it is flash vaporized. Flash vaporization therefore occurs under conditions so that there is no distillation effect in the conversion of the mixed solution liquid to the mixed solution vapor. Advantageously, material-removing vapor may be continuously contacted with a substrate in a highly controlled manner. Thus, a controlled ratio of constituents in the vapor may be consistently processed to provide a controlled environment over the substrate for any desired period of time. This consistent environment around the substrate over a prolonged period of time has been very difficult to achieve prior to the present invention.

A particularly preferred embodiment of flash vaporization comprises a step of reducing the pressure on a liquid to below the liquid's vapor pressure. Thus, in a preferred embodiment, the material-removing liquid has a first liquid vapor pressure and the flash vaporizing step comprises reducing the pressure on the material-removing liquid to below the first liquid vapor pressure to a level sufficient to effect flash vaporization. The reduction of pressure may be accomplished by any appropriate mechanism, such as by flow of liquid through an orifice or a restriction in a portion of the conduit, particularly by drawing a vacuum on the material-removing liquid downstream of an orifice or restriction in the conduit. In one preferred embodiment, the material-removing liquid is heated prior to the pressure reducing step.

Various combinations of pressure reducing techniques may be used simultaneously or sequentially. In a preferred embodiment, the flash vaporizing step comprises reducing pressure on the material-removing liquid and mixing a gas different from the material-removing liquid with the material-removing liquid during the pressure reducing step such that partial pressure of the material-removing vapor is reduced to below the liquid vapor pressure to a level sufficient to effect flash vaporization. The gas as described above may be functional in a process of treating the microelectronic substrate, or optionally maybe an inert carrier gas. Preferred carrier gases are selected from the group consisting of nitrogen, hydrogen, argon or a combination thereof.

Alternatively, the material-removing liquid may be flash vaporized by application of heat to a level sufficient to effect flash vaporization. More specifically, the material-removing liquid has a first boiling temperature at a given pressure. Flash vaporization is carried out by heating the material-removing liquid to a temperature above the first boiling temperature to a level sufficient to effect flash vaporization.

Heating of the material-removing liquid may optionally be accomplished by flowing the liquid onto, across, through, or sufficiently close to a heated member, such as a hot plate or another hot surface, such that the temperature of the material-removing liquid is raised above its boiling temperature (at a given pressure, e.g., at atmospheric or non-atmospheric pressure). Rather than or in addition to using a heated member, the material-removing liquid could be “heat-flashed” by injecting heated gas into the conduit or chamber, delivering microwave energy to the conduit or chamber, or using infrared heaters and/or other radiative heaters to heat the conduit or chamber.

In a particularly preferred embodiment of the present invention, the material-removing liquid is a mixture of at least two liquid constituents, wherein the at least two liquid constituents have at least two different boiling temperatures at a given pressure. In this embodiment, the heating step preferably comprises heating the material-removing liquid above the two different boiling temperatures to a level sufficient to effect flash vaporization of both liquid constituents.

As noted above, flash vaporization may be carried out using either heat or pressure techniques. Alternatively, both heat and pressure reduction steps may be combined to flash vaporize the liquid composition. Additional physical manipulation techniques with respect to the liquid may be carried out in order to facilitate the flash vaporization of the material-removing liquid. For example, the material-removing liquid may be atomized during or prior to the heating and/or pressure reducing step. Atomization may be accomplished, for example, by utilizing an ultrasonic spray nozzle or an atomizing spray nozzle. Preferably, the liquid material is mixed with nitrogen prior to flow through the spray nozzle.

Advantageously, small amounts of liquid may be flash vaporized by injection to a vaporization zone or by other suitable technique. In an embodiment of the present invention, the material-removing liquid may be flash vaporized to a material-removing vapor as a batch process. Alternatively and preferably, the material-removing liquid is flash vaporized to a material-removing vapor as a continuous process. In a particularly preferred embodiment, flash vaporization can also be conducted in a continuous flow process. In this system, liquid continually flows into a flash vaporization zone, where the pressure is either rapidly decreased or the temperature rapidly increased such that the vapor exits the flash vaporization zone at the same mass flow rate as liquid enters.

The method of the present invention finds particular advantage in generation and delivery of the material-removing liquids that comprise at least two liquid constituents. This is the case because flash vaporization can immediately vaporize liquids without a distillation effect. This method is particularly useful in generating and delivering vapor from a material-removing liquid that is a mixture of two or more liquid constituents that form an azeotrope, wherein the resulting vapor may contain the liquid constituents in any ratio, including ratios other than the azeotropic ratio of the liquid constituents. Further, this method may advantageously be used to deliver a composition comprising two or more constituents that have different vapor pressures, but which do not form an azeotrope. These types of compositions are extremely difficult to provide in a constant concentration in the vapor phase, because of their tendency to change in concentration from one moment to the next as they are vaporized from a liquid solution. This concentration change is because the constituents will vaporize at different rates because of their different volatilities. The vapor generated from the process of the present invention contains the constituents in the same content ratio as the source liquid. As such, the vapor may be tailored compositionally to be most effective for removing the material from the microelectronic substrate without the limitations previously experienced as a result of the difficulty of providing a vapor of any specific chemical composition due to distillation or azeotropic effects.

The material-removing vapor may optionally be used in conjunction with other agents that are contacted with a substrate, either simultaneously or sequentially. These other agents may be provided in the same flash vaporization process, in a parallel flash vaporization process, in a sequential flash vaporization process, or any other appropriate application technique carried out sequentially for sequential delivery to a substrate or in parallel for simultaneous delivery to a substrate. Other appropriate application techniques include liquid spray or immersion of the substrate in liquid, application of a vapor using techniques other than flash vaporization, or application of a gas.

In a preferred embodiment, the material-removing vapor comprises an etchant and may be used to etch or strip a substrate. Thus, various impurities or sacrificial materials; such as thermal, native or chemical oxides, doped oxides, C. V. D. grown oxides (e.g. TEOS), spin on glasses (“SOG”) and the like; may be removed from the microelectronic substrate by a material-removing vapor comprising an etchant in the process of the present invention.

Various etchants may be used to effect etching and stripping of materials on substrates in accordance with the present invention. Preferably, the etchant is selected from the group consisting of hydrogen fluoride, hydrogen chloride, hydrogen bromide, ozone, other like reactant materials and combinations thereof.

In an alternative embodiment, the material-removing vapor comprises a component that enhances the effectiveness of an etchant upon a substrate. This component is used in conjunction with a separate etchant. Etchant enhancing components act to enable or, if you will, catalyze the etching or stripping action of the etchant. Etchant enhancing components are particularly desirable for certain etchants under certain conditions of use, wherein but for the presence of these etchant enhancing components, the etching effect by the etchant may be reduced, possibly to the point to which the etching process is ultimately not effective or not feasible.

Such etchant enhancing components may be contacted with the substrate prior to application of the etchant as a pretreatment, during application of the etchant, or following application of the etchant. Preferred examples of such enhancing components, especially for HF etchants, include components selected from the group consisting of water, alcohol (such as methanol, ethanol, i-propanol and n-propanol), carboxylic acids (such as acetic acid and formic acid), mixtures of these components and the like.

Alternatively, the material-removing composition may be a blend of an etchant, together with an etchant enhancing component, wherein this blend is flash vaporized from a single liquid composition. As above, preferred examples of such enhancing components, especially for HF etchants, include ingredients selected from the group consisting of water, alcohol, (such as methanol, ethanol, i-propanol and n-propanol), carboxylic acids (such as acetic acid and formic acid), combinations of such ingredients and the like.

Particularly preferred compositions to be contacted with microelectronic substrates for etching or stripping include HF/water mixtures, HF/alcohol mixtures and particularly HF/IPA mixtures, HF/N₂/H₂O mixtures and HF/alcohol/water mixtures. Compositions of HF and water or of HF and alcohol form azeotropes, so that vapors made from an evaporative process from a liquid comprising these constituents have the composition of their respective azeotropic ratios. However, the process of the present invention easily provides vapor compositions having these constituents in any desired ratio. Thus, the present invention allows a user to produce an HF/water vapor mixture (or other noted mixtures) from highly diluted (e.g., 1:1000) to highly concentrated (e.g., 0.1000:1) by starting with a liquid mixture having the desired HF-water ratio (or a ratio of the other noted liquids).

In another alternative of the present invention, the material-removing vapor may be a rinsing vapor. As noted above, a rinsing vapor operates by solvation in removing material on the substrate. Such materials may, for example, include a prior processing ingredient, such as an etching or stripping ingredient. Preferred examples of rinsing vapors include compositions comprising DI water; alcohols such as isopropyl alcohol, ethanol and methanol; ketones; and other organic solvents. Mixtures of these materials are particularly preferred, such as alcohol/water and preferably isopropyl alcohol/water. The proportion of IPA and water can be varied from a ratio of 100:1, 50:1, 25:1, 10:1, 7.5:1, 5:1, 1:1, or other useful ratios. This proportion may be chosen to more effectively solvate some materials or to affect the surface tension of the overall composition. In some circumstances, the selection of specific ratio of alcohol to water will reduce the chance of an unintended ignition of IPA through the process or to maximize process performance, such as cleaning or etching uniformity.

In another embodiment of the present invention, the material-removing vapor may be a drying vapor. In a drying step, a surface-tension reducing liquid can be flash vaporized and optionally mixed with a higher temperature drying gas, such as nitrogen. In a preferred embodiment, this vapor composition may be directed to the interface of water and the substrate to assist in drying the substrate by the Marangoni effect. Examples of suitable drying vapors comprise polar organic compounds selected from the group consisting of alcohols, ketones and combinations thereof. A particularly preferred polar organic compound for use in drying vapors is isopropyl alcohol.

### Detailed Description of the Drawings

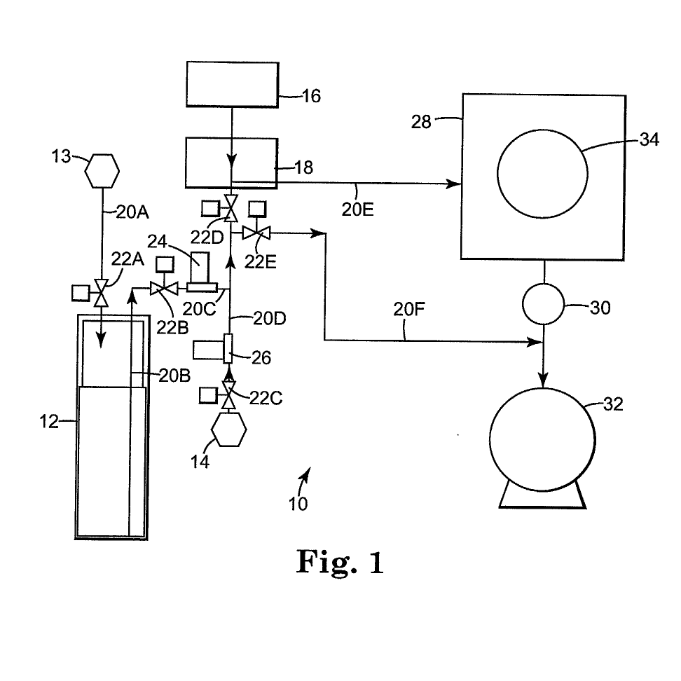

Turning now to the drawings, wherein like numerals denote like parts, FIG. 1 illustrates one embodiment of the present invention. Note that constituents within and sections of apparatus 10 are, by themselves, considered to be embodiments of the present invention. FIG. 1 is also useful for explaining the inventive method, as is described later herein. Variations of apparatus 10 are contemplated, some of which are also described herein.

As shown in FIG. 1, apparatus 10 includes a source of a material-removing liquid, e.g., a pressure vessel 12. Apparatus 10 can further include a source of a carrier gas (e.g., nitrogen gas) 14, a source of other processing gases 16, a hotbox 18, conduit 20A-F, valves 22A-E, a liquid flow controller 24, gas flow controller 26, a vacuum chamber 28, a throttle valve 30 and a vacuum pump 32. The vacuum chamber 28 is configured to support one or more substrate 34 and may include gas orifices (not shown) through which gas may enter and exit and spray nozzles (not shown) for directing the vapor within the chamber 28.

The pressure vessel 12 can be a commercially available vessel used for containing the material-removing liquid. The nitrogen source 14 can be a standard nitrogen tank/valve/conduit combination. The liquid flow controller 24 can be a standard liquid mass flow controller such as an LX-1200 MVC available from Aera Corporation. Alternatively, the liquid flow controller could be a metering pump or another device. The gas flow controllers 26 can be standard gas mass flow controllers, such as Model 8100 available from Kinetics, Inc., Yorba Linda, Calif.

The hotbox 18 can simply be an enclosure containing a heated gas or liquid (e.g., air, nitrogen gas or water) heated to an appropriate temperature, such that the liquids and/or gases flowing through conduit within the hotbox 18 are heated. The gas or liquid inside the hotbox 18 can be heated to any useful temperature as a means for preventing or reducing condensation of any vapor flowing through such conduit. When using, for example, an HF gas, a useful temperature range may be above 40 degrees Celsius, more preferably between 40 and 60 degrees Celsius, more preferably between 49 and 51 degrees Celsius. In addition to positioning the conduit containing the HF gas within the hotbox 18, the conduit containing the IPA/water liquid mixture may be positioned within the hotbox 18 to heat this mixture and cause it to be flash vaporized using a less severe pressure drop. When prevention or reduction of condensation is not a significant problem or another means is employed, the hot box 18 may be eliminated.

The conduit 20 can be, for example, electropolished 316 Stainless Steel tubing available from Cardinal UHP, St. Louis, Mo. The vacuum chamber 28 is known in the art, an example of which is described in detail below and described in still greater detail in pending U.S. Pat. Application Ser. No. 09/440,388 (entitled Processing Apparatus For Microelectronic Devices In Which Polymeric Bellows Are Used To Help Accomplish Substrate Transport Inside the Apparatus), which is hereby incorporated by reference.

When the apparatus 10 (or a variation thereof) is in use, the material-removing liquid vessel 12 can be pressurized by applying a controlled gas pressure, e.g., nitrogen from gas tank 13 (through conduit 20A and valve 22A) to the head space within the vessel 12. This pressure provides a driving force for flowing the material-removing liquid up through conduit 20B extending from the lower portion of the vessel 12 and out the top of the vessel 12. The apparatus for this could include the use of gravity, a pump and a combination of these two approaches and a combination of the gas pressure with one or both of gravity and a pump.

This material-removing liquid can flow through the liquid flow controller 24 and into conduit 20C. When the material-removing liquid flows through the flow control valve of the liquid flow controller 24, the vacuum drawn by the inline vacuum pump 32 (via the vacuum chamber 28) reduces the pressure upon the material-removing liquid to below the vapor pressure of the material-removing liquid (at a given temperature, e.g., room temperature or a higher or lower temperature). This causes the material-removing liquid to flash vaporize, forming a material-removing vapor within the conduit 20 downstream of the liquid flow controller 24. Generally, the pressure drop may be chosen based on the liquid being flash vaporized.

A carrier gas, such as nitrogen gas, can be mixed with the vapor using one or both of valve 22C and gas mass flow controller 26, with the resulting mixture caused to flow into the vacuum chamber 28 through valve 22D and conduit 20E to process the substrate 34. For use on an in-process microelectronic substrate, one preferred flow rate of the nitrogen can be 1000 SCCM, though a different flow rate may be chosen based on the equipment, substrate and gases being employed. This mixture can be routed to the chamber 28 until the desired pressure is reached within the chamber 28, at which point the throttle valve 30 can be used to maintain the pressure more consistently. Apparatus 110 is preferably provided with a bypass comprising valve 22E connected to conduit 20F, whereby the carrier gas may be continuously run from the carrier gas source 14 to vacuum pump 32. This allows for continuous vaporization of the material removing liquid, thereby providing better control of the vapor. Because the vaporization process is continuous, no undesired variation in concentration of the vapor occurs due to the starting and stopping of the vaporization process.

When using hydrogen fluoride (HF) gas as the etchant, it can be mixed with a carrier gas, such as nitrogen. Preferred flow rates for the HF gas and nitrogen for use on an in-process microelectronic substrate are 1000 SCCM and 200 SCCM, respectively. This etching gas mixture preferably flows into the processing chamber 28 and etch the substrates 34 for a time sufficient to remove the material. Preferably, the etching step lasts for approximately 50 seconds. This etching gas can be routed into the chamber 28 with the IPA/N₂ gas mixture (or IPA/N₂/H₂O gas mixture or other cleaning gas mixture). At the end of the etching process, the IPA/N₂ gas mixture (or IPA/N₂/H₂O gas mixture) can be diverted to vacuum and the flow of the HF and N₂ gases can be shut off. Other useful flow rates and useful etching times than those just described are contemplated.

A direct liquid injection system referred to as the DLI-25C system (available from MKS Instruments Inc. andover, Mass.) may be used within apparatus 10 to flash vaporize the material-removing liquid. Such a system could be used in place of the liquid mass flow controller 24 and could be used with or without the vacuum being pulled by the vacuum pump 32. A bulletin entitled DLI25C-1/99 in the MKS website, mksinst.com, describes and illustrates the DLI-25C system.

Other variations of the apparatus 10 and corresponding methods for using the same are contemplated. For example, in place of the liquid mass flow controller 24, another device having an orifice, nozzle, flow restriction valve or restricted region of conduit could be used in conjunction with the vacuum pump 32.

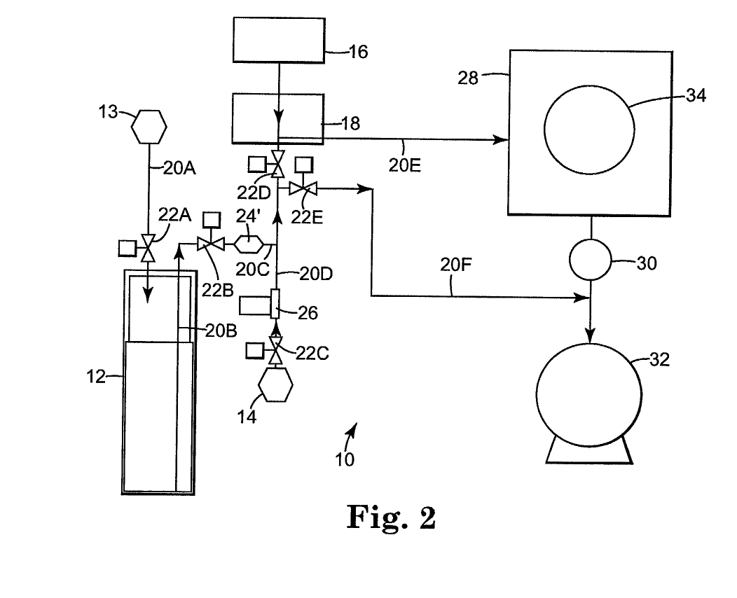

FIG. 2 schematically illustrates a “heat-flashing” assembly 24′ within apparatus 10′, which could include one or more of the above-noted heat-flashing means. As shown in FIG. 2, this heat-flashing approach may be used in conjunction with the previously described pressure-drop approach by virtue of the inline vacuum pump 32. Alternatively, this heating-flashing approach may be accomplished without reducing the pressure on the material-removing liquid (and even with a pressure increase as long as the temperature of the material-removing liquid is sufficiently raised to flash vaporize). Further, this heat-flashing approach could include the use of a flow restrictor, such as the previously discussed flow controller or one of the later described restrictors.

Other flash evaporating approaches may be used in place of or in addition to the approaches noted above. For example, an ultrasonic spray nozzle may be used to atomize the liquid into fine droplets or mist (available from Sonnetech Co. of Poughkeepsie, N.Y.). The vaporization of this mist could be completed in several ways. One way would be to atomize this mist within a zone (not shown) in which sufficient heat is transferred to the mist. This heat transfer could be via heated gas within the zone, microwave energy within the zone, infrared heaters, other radiative heaters and/or hot surfaces within the zone onto which the mist is applied after atomization.

An alternative to the hotbox 18 shown in FIGS. 1 and 2 could be one that encloses more or less of apparatus 10 or 10′ than that which is shown in these Figs. For example, the source of liquid processing fluid 12 and/or more of the conduit 22 can be enclosed within the hotbox. Or, rather than or in addition to the hotbox 18, heat tape, heat blankets, other conductive heater, heat lamps and other radiative heaters, applied flame, generally heated environment without or without convective heat flow and other known heating devices can be used to heat the material-removing liquid, processing gases, or both. In another embodiment, the hotbox 18 may be eliminated entirely.

Alternative embodiments other than that shown in FIGS. 1 and 2 could involve, for example, an atmospheric chamber in place of the vacuum chamber 28. Alternatively, a chamber operating at a pressure higher than atmospheric could be used. Such other chambers can be used in conjunction with the other embodiments described herein.

Another alternative embodiment with regard to apparatus 10 or 10′ can be multiple containers of material-removing liquids rather than the single pressure vessel 12 shown in FIG. 1. For example, separate containers of water, a liquid HF composition, other liquids and combinations of the foregoing could be employed and mixed prior to flash vaporization using known equipment (e.g., valving, flow controllers, orifices and the like).

Apparatus 10 and 10′ and variations thereof may be equipped with logic devices or other control devices (not shown) for automating one or more aspects of their operation. For example, a microprocessor controlled system may be used and sensors can be included to monitor operations and particular criteria, such as fluid flows including flow rates, pressures, temperatures, as well as other criteria useful for the inventive apparatus and method.

In another arrangement, a flow of flash vapor into the chamber 28 can follow a process step in which a liquid-phase cleaning liquid has been sprayed onto the substrate 34. This liquid spray process can involve the use of spray-processing apparatus such as those available from FSI International, Chaska, Minn., e.g., under one or more of the trade designations MERCURY®, SATURN®, TITAN®, or ZETA®. Pending U.S. Pat. Application Ser. No. 09/580,757, which is incorporated by reference herein, discloses apparatus of these types.

When reading the above, one of ordinary skill in the art will appreciate that the invention includes still further variations than those specifically described, which should be considered to be within the scope of the invention.

What is claimed is:

1. A method for removing material from a surface of an in-process, microelectronic substrate comprising:
providing a material-removing composition in liquid form;
flash vaporizing the material-removing liquid, thereby forming a material-removing vapor; and
contacting the material-removing vapor with the material.

2. The method of claim 1, wherein the material-removing liquid has a first liquid vapor pressure, wherein the flash vaporizing step comprises reducing the pressure on the material-removing liquid to below the first liquid vapor pressure to a level sufficient to effect flash vaporization.

3. The method of claim 2, wherein the material-removing liquid is a mixture of at least two liquid constituents, wherein the at least two liquid constituents have at least two vapor pressures at a given temperature and wherein the pressure reducing step reduces the pressure of the material-removing liquid below the two different vapor pressures to a level sufficient to effect flash vaporization of both liquid constituents.

4. The method of claim 2, wherein the reducing pressure step comprises flowing liquid into an area of reduced pressure in a continuous process.

5. The method of claim 2, wherein the material-removing liquid is heated prior to the pressure reducing step.

6. The method of claim 2, wherein the material-removing liquid is atomized during or prior to the pressure reducing step.

7. The method of claim 1, wherein the material-removing liquid has a first liquid vapor pressure and wherein the flash vaporizing step comprises
a) providing a material-removing composition in the form of a liquid having a material-removing vapor associated therewith;
b) introducing a gas different from the material-removing composition, thereby reducing the partial pressure of the material-removing vapor to below the first liquid vapor pressure to a level sufficient to effect flash vaporization of the material-removing liquid.

8. The method of claim 7, wherein the gas is selected from the group consisting of nitrogen, hydrogen, argon or a combination thereof.

9. The method of claim 7, further comprising the step of reducing pressure on the material-removing liquid prior to or at the same time as introduction of the gas.

10. The method of claim 2, comprising flowing the material-removing liquid through a restriction as or just before pressure upon the material-removing liquid is reduced.

11. The method of claim 10, wherein the restriction is provided by one of an orifice and a restricting section of conduit.

12. The method of claim 1, wherein the material-removing liquid has a first boiling temperature at a given pressure, wherein the flash vaporizing step comprising heating the material-removing liquid to a temperature above the first boiling temperature to a level sufficient to effect flash vaporization.

13. The method of claim 12, wherein the heating step comprises flowing the material-removing liquid onto, through, or adjacent a heat source as a continuous process.

14. The method of claim 12, wherein the material-removing liquid is a mixture of at least two liquid constituents, wherein the at least two liquid constituents have at least two different boiling temperatures at a given pressure and wherein the heating step heats the material-removing liquid above the two different boiling temperatures to a level sufficient to effect flash vaporization of both liquid constituents.

15. The method of claim 12, wherein the material-removing liquid is atomized during or prior to the heating step.

16. The method of claim 12, wherein the material-removing liquid comprises at least two constituents in the liquid state that form an azeotrope with each other at a predetermined azeotropic ratio, and the vapor generated by flash vaporization contains the two constituents in a ratio other than the azeotropic ratio.

17. The method of claim 1, wherein the material-removing liquid is flash vaporized to a material-removing vapor as a batch process.

18. The method of claim 1, wherein the material-removing liquid is flash vaporized to a material-removing vapor as a continuous process.

19. The method of claim 1, wherein the material-removing vapor comprises an etchant.

20. The method of claim 19, wherein the etchant is selected from the group consisting of hydrogen fluoride, hydrogen chloride, hydrogen bromide, ozone and combinations thereof.

21. The method of claim 1, wherein the material-removing vapor comprises a component that enhances the effectiveness of an etchant upon a substrate.

22. The method of claim 21, wherein the component that enhances the effectiveness of an etchant comprises an ingredient selected from the group consisting of alcohol, water, carboxylic acids and combinations thereof.

23. The method of claim 21, wherein the component that enhances the effectiveness of an etchant comprises an ingredient selected from the group consisting of water, methanol, ethanol, i-propanol, n-propanol, acetic acid, formic acid and combinations thereof.

24. The method of claim 21, wherein the component that enhances the effectiveness of an etchant is a water/i-propanol mixture.

25. The method of claim 19, wherein the material-removing vapor further comprises a component that enhances the effectiveness of an etchant upon a substrate.

26. The method of claim 25, wherein the component that enhances the effectiveness of an etchant comprises an ingredient selected from the group consisting of water, alcohol, carboxylic acids and combinations thereof.

27. The method of claim 25, wherein the component that enhances the effectiveness of an etchant comprises an ingredient selected from the group consisting of water, methanol, ethanol, i-propanol, n-propanol, acetic acid, formic acid and combinations thereof.

28. The method of claim 25, wherein the component that enhances the effectiveness of an etchant is a water/i-propanol mixture.

29. The method of claim 25, wherein the material-removing vapor is selected from the group consisting of a) a mixture of hydrogen fluoride and water, b) a mixture of hydrogen fluoride and alcohol, and c) a mixture of hydrogen fluoride, alcohol and water.

30. The method of claim 1, wherein the material-removing vapor is a rinsing vapor.

31. The method of claim 30, wherein the rinsing vapor is selected from the group consisting of water, alcohol and combinations thereof.

32. The method of claim 1, wherein the material-removing vapor is a drying vapor.

33. The method of claim 32, wherein the drying vapor is selected from the group consisting of alcohols, ketones and combinations thereof.

34. The method of claim 32, wherein the drying vapor comprises isopropyl alcohol.

35. The method of claim 1, comprising positioning the in-process, microelectronic substrate within a processing chamber, wherein the contacting step comprises flowing the material-removing vapor into the processing chamber.

36. The method of claim 33, wherein the processing chamber comprises a vacuum chamber, wherein gas within the vacuum chamber is at least partially evacuated prior to the flash vaporization step.

37. The method of claim 1, wherein the in-process, microelectronic substrate is an in-process, semiconductor wafer substrate.
